(19) United States
(12) Patent Application Publication
(10) Pub. No.: US 2026/0285226 A1
(43) Pub. Date: Sep. 24, 2026

(54) TRAILER LIGHTING MONITORING, INSPECTION, DIAGNOSTIC, AND COMPLIANCE SYSTEM

(71) Applicants: David William Christ, Staunton, VA (US); Lynette Rene Christ, Staunton, VA (US)

(72) Inventors: David William Christ, Staunton, VA (US); Lynette Rene Christ, Staunton, VA (US)

(21) Appl. No.: 19/631,074

(22) Filed: Mar. 27, 2026

Related U.S. Application Data
(63) Continuation-in-part of application No. 19/570,054, filed on Mar. 17, 2026.
Application No. 19/570,054 is a continuation-in-part of application No. 19/030,775, filed on Jan. 17, 2025.

(51) Int. Cl. B60Q 11/00; B60R 16/02; G01R 31/00; G01R 31/52; G08B 21/18

(52) U.S. Cl. CPC B60Q 11/005; G01R 31/007; G01R 31/52; G08B 21/185; B60Q 2900/40; B60R 16/0207

(57) ABSTRACT

A trailer lighting monitoring system is provided comprising a sensing module configured to detect electrical characteristics of one or more trailer lighting circuits, a processing module configured to determine an operational status of the one or more trailer lighting circuits based on the detected electrical characteristics, and a notification module configured to generate an alert indicative of a malfunction condition. The system may further include an inspection module configured to automatically test the trailer lighting circuits upon connection of a trailer, a diagnostics module configured to identify electrical fault conditions including open circuits, short circuits, voltage drops, and intermittent faults, and a compliance module configured to record operational data including inspection results, timestamps, and fault history. The system may operate continuously during vehicle operation and may be implemented within a wiring harness, electrical connector, vehicle electrical system, trailer system, or distributed architecture. In certain embodiments, the processing module may utilize statistical analysis, machine learning, or artificial intelligence to analyze electrical characteristics, identify patterns, and predict failures prior to occurrence. The system improves roadway safety by providing continuous verification of trailer lighting functionality and reducing the likelihood of undetected failures during operation.

### CROSS-REFERENCE TO RELATED APPLICATIONS

This application is a continuation-in-part of U.S. application Ser. No. 19/030,775, filed Jan. 17, 2025, entitled “Continuous Monitoring Trailer Adapter,” and is also a continuation-in-part of U.S. application Ser. No. 19/570,054, filed Mar. 17, 2026, entitled “Telematics-Enabled Trailer Safety and Monitoring System,” the contents of each of which are incorporated herein by reference in their entirety.

### FIELD OF THE INVENTION

The present invention relates generally to vehicle safety and monitoring systems, and more particularly to systems and methods for monitoring, inspecting, diagnosing, and reporting the operational status of trailer lighting systems associated with towing vehicles.

The invention further relates to integrated and distributed electrical monitoring systems capable of functioning within vehicle electrical architectures, trailer systems, wiring harnesses, and connector interfaces. The system is further configured to interface with telematics systems, cloud-based platforms, and user interfaces for real-time monitoring and reporting. The disclosed system is applicable to conventional vehicles, commercial fleets, advanced driver-assistance systems, and autonomous vehicle systems.

### BACKGROUND OF THE INVENTION

Trailer lighting systems are critical for roadway safety, providing essential signals such as braking, turning, and running lights. These systems are typically powered through electrical connections between a towing vehicle and a trailer.

However, conventional systems do not provide real-time feedback regarding their operational status. Failures such as open circuits, short circuits, wiring degradation, or intermittent electrical faults may occur without the knowledge of the vehicle operator.

Existing inspection methods rely heavily on manual visual checks, which are subject to human error and cannot detect failures occurring during operation. Additionally, there is a lack of integrated diagnostic systems capable of identifying specific fault conditions, as well as a lack of automated compliance tracking for fleet management and regulatory reporting.

With the evolution of connected and autonomous vehicle systems, there is an increasing need for intelligent monitoring systems that provide continuous, automated, and data-driven verification of trailer lighting performance.

### SUMMARY OF THE INVENTION

The present invention provides a comprehensive trailer lighting monitoring system configured to continuously detect electrical characteristics of one or more trailer lighting circuits and determine an operational status in real time.

The system includes a sensing module configured to detect electrical characteristics including voltage, current, resistance, and signal behavior associated with the trailer lighting circuits, and a processing module configured to evaluate the detected characteristics to determine operational status and identify fault conditions.

In various embodiments, the system may include an inspection module configured to automatically test the trailer lighting circuits upon connection of a trailer and, in some cases, during operation. A diagnostics module is configured to identify electrical faults including open circuits, short circuits, voltage anomalies, and intermittent failures, and may further provide diagnostic analysis of circuit performance.

A notification module is configured to generate alerts based on detected fault conditions or system states, which may be communicated to a driver, vehicle system, fleet management system, maintenance system, or other external platform. A compliance module may record operational data including inspection results, diagnostic data, timestamps, and fault history for regulatory compliance, maintenance tracking, and fleet analytics.

The system may be implemented within a wiring harness, electrical connector, vehicle electrical system, trailer system, or a distributed architecture. In certain embodiments, the system interfaces with telematics systems, cloud networks, user interfaces, and advanced vehicle systems, including fleet management platforms and automated driving systems, to enable real-time monitoring, reporting, and integration with modern transportation technologies. In certain embodiments, the system may further utilize predictive analysis to identify potential failures prior to occurrence.

### BRIEF DESCRIPTION OF THE DRAWINGS

FIG. 1 illustrates a system overview of the monitoring architecture.

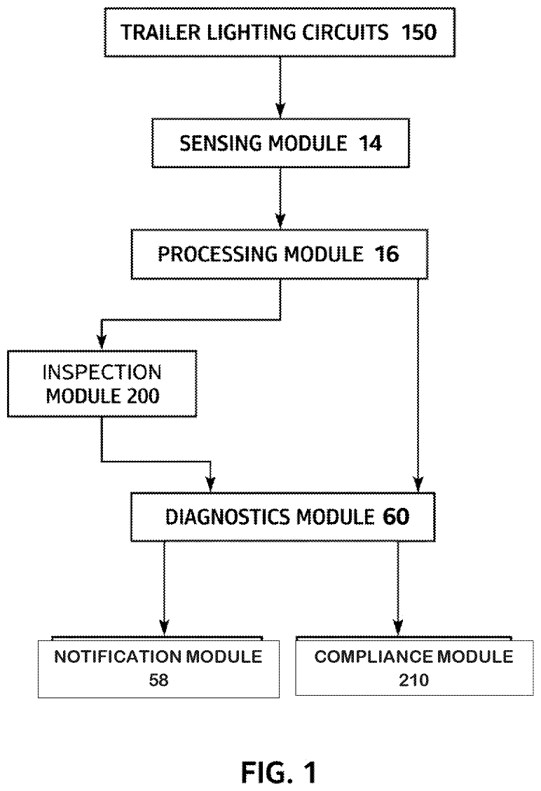

FIG. 2 illustrates a system communication architecture including telematics, cloud network, and user interface.

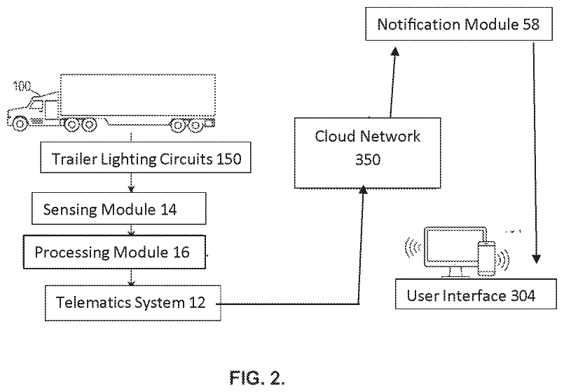

FIG. 3 illustrates a processing, telematics, and notification architecture.

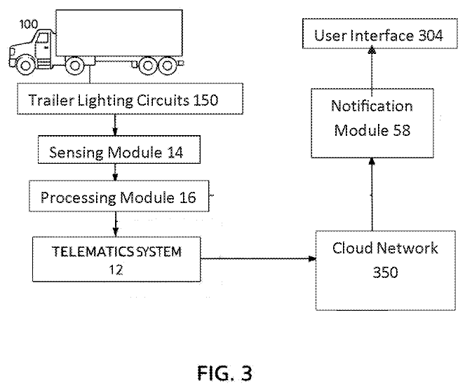

FIG. 4 illustrates an automated inspection and alert generation process flow.

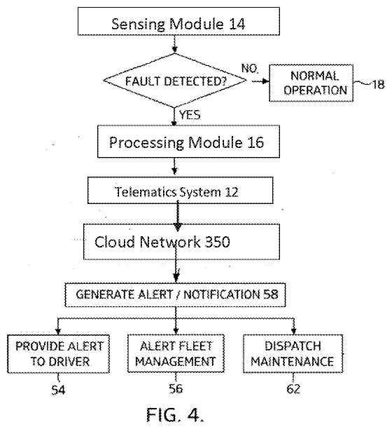

FIG. 5 illustrates a physical implementation of the monitoring system within a trailer and vehicle configuration.

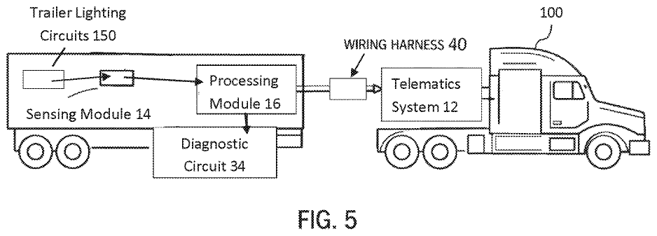

FIG. 6 illustrates a diagnostic and alert generation system.

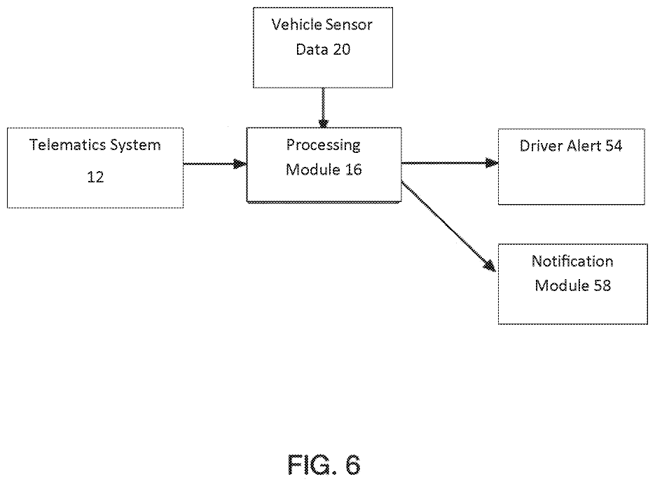

FIG. 7 illustrates a distributed monitoring and notification system architecture.

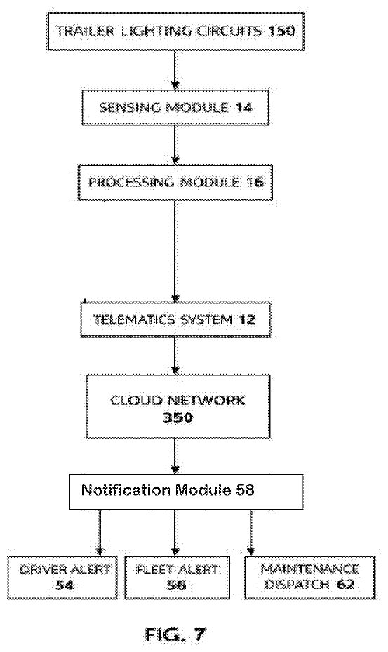

### REFERENCE NUMBERS

12—Telematics System
14—Sensing Module
16—Processing Module
18—Normal Operation
20—Vehicle Sensor Data
34—Diagnostic Circuit
40—Wiring Harness
54—Driver Alert
56—Fleet Alert
58—Notification Module
100—Truck
150—Trailer Lighting Circuits
200—Inspection Module
210—Compliance Module
304—User Interface
350—Cloud Network

### DETAILED DESCRIPTION OF THE INVENTION

The present invention provides a trailer lighting monitoring, inspection, diagnostic, and compliance system configured to operate within a vehicle-trailer electrical architecture. The system comprises multiple functional modules including a sensing module (14), a processing module (16), an inspection module (200), a diagnostics module (60), a notification module (58), and a compliance module (210), each configured to cooperate to monitor and evaluate trailer lighting circuits (150).

The sensing module (14) is configured to detect electrical characteristics associated with one or more trailer lighting circuits (150). The detected electrical characteristics may include, but are not limited to, voltage, current, resistance, signal patterns, signal timing, frequency behavior, load signatures, and transient electrical events. In certain embodiments, the sensing module (14) may be configured to detect intermittent conditions and time-dependent variations in circuit behavior to enable identification of non-persistent faults.

The sensing module (14) provides detected electrical data to the processing module (16). The processing module (16) is configured to evaluate the electrical characteristics to determine an operational status of the trailer lighting circuits (150) and to identify potential malfunctions. The processing module (16) may utilize rule-based logic, threshold analysis, statistical modeling, or advanced algorithms including machine learning and artificial intelligence to improve detection accuracy and predictive capability.

The processing module (16) may operate in multiple modes, including an inspection mode, a continuous monitoring mode, and an event-driven mode. In the inspection mode, the system may automatically test trailer lighting circuits (150) upon connection of a trailer by sequentially activating one or more circuits and verifying proper functionality. In the continuous monitoring mode, the system operates during vehicle operation to continuously evaluate circuit performance. In the event-driven mode, the system responds to detected anomalies or fault conditions.

The inspection module (200) may be configured to perform automated inspection of trailer lighting circuits (150). The inspection module (200) may sequentially activate lighting functions, verify expected responses, and determine whether the system is operating correctly. In some embodiments, the inspection module (200) may operate periodically or continuously to ensure ongoing verification of system performance.

The diagnostics module (60) is configured to identify fault conditions associated with the trailer lighting circuits (150). Such fault conditions may include, but are not limited to, open circuits, short circuits, voltage anomalies, intermittent faults, degraded wiring conditions, connector faults, and abnormal electrical behavior. The diagnostics module (60) may further classify detected faults and generate diagnostic information indicative of fault type, severity, and location.

The notification module (58) is configured to generate alerts based on detected fault conditions or system states. Alerts may be provided through visual, audible, or electronic interfaces. In various embodiments, alerts may be directed to a driver (54), a fleet management system (56), a maintenance dispatch system (62), a remote monitoring system, or an automated driving system. The notification module (58) may generate different alert types based on severity, priority, or system conditions.

The compliance module (210) is configured to record operational data associated with the trailer lighting monitoring system. The recorded data may include inspection results, diagnostic results, timestamps, operational history, and fault events. Such data may be used for regulatory compliance, maintenance tracking, audit reporting, and fleet analytics.

The system may be implemented in a distributed architecture and may be located in one or more positions within the vehicle-trailer electrical system. For example, the system or portions thereof may be integrated within a wiring harness (40), an electrical connector, a trailer system, a vehicle system, or combinations thereof. The system may communicate between components through wired or wireless communication pathways.

The processing module (16) may communicate with a telematics system (12), which is configured to transmit data to a cloud network (350). The cloud network (350) may facilitate remote monitoring, data storage, analytics, and communication with one or more user interfaces (304). In certain embodiments, the telematics system (12) serves as a communication gateway between the vehicle-trailer system and external systems.

The cloud network (350) may communicate with the notification module (58) and the user interface (304) to provide real-time alerts, system status updates, and historical data. The user interface (304) may include mobile devices, in-cab displays, fleet management platforms, or other computing devices.

In certain embodiments, the system may incorporate artificial intelligence or machine learning techniques to analyze electrical patterns, identify anomalies, and predict failures prior to occurrence. The system may adapt to changing conditions over time and improve diagnostic accuracy based on historical data.

The system is applicable to conventional vehicles, commercial fleets, advanced driver-assistance systems (ADAS), and autonomous vehicle systems. The system may be configured to integrate with automated driving systems to provide safety-critical monitoring of trailer lighting functionality.

The present invention improves roadway safety by providing continuous verification of trailer lighting system functionality, reducing the likelihood of undetected failures, enabling proactive maintenance, and supporting compliance with safety regulations.

What is claimed is:

1. A trailer lighting monitoring system comprising: a sensing module configured to detect electrical characteristics of one or more trailer lighting circuits; a processing module configured to determine an operational status of the one or more trailer lighting circuits based on the detected electrical characteristics; a diagnostics module configured to identify a malfunction condition of the one or more trailer lighting circuits; and a notification module configured to generate an alert indicative of the malfunction condition, wherein the system is configured to continuously monitor the one or more trailer lighting circuits during operation of a vehicle.

2. The system of claim 1, wherein the sensing module is configured to detect electrical characteristics including voltage, current, resistance, signal timing, or frequency behavior.

3. The system of claim 1, further comprising an inspection module configured to automatically test the one or more trailer lighting circuits upon connection of a trailer.

4. The system of claim 3, wherein the inspection module sequentially activates the trailer lighting circuits to verify functionality.

5. The system of claim 1, wherein the diagnostics module is configured to detect open circuit conditions.

6. The system of claim 1, wherein the diagnostics module is configured to detect short circuit conditions.

7. The system of claim 1, wherein the diagnostics module is configured to detect voltage drops or intermittent electrical faults.

8. The system of claim 1, further comprising a compliance module configured to record operational data including inspection results, timestamps, and fault history.

9. The system of claim 1, wherein the system is implemented within at least one of a wiring harness, an electrical connector, a vehicle electrical system, or a trailer electrical system.

10. The system of claim 1, wherein the processing module utilizes machine learning or artificial intelligence to analyze electrical characteristics.

11. The system of claim 10, wherein the system is configured to predict a malfunction condition prior to occurrence.

12. The system of claim 1, wherein the notification module is configured to provide alerts through at least one of a visual interface, an audible interface, or a vehicle display.

13. The system of claim 1, wherein the notification module is configured to provide alerts to a vehicle control system or an automated driving system.

14. A vehicle-trailer monitoring system comprising: a vehicle electrical system; a trailer lighting circuit electrically coupled to the vehicle electrical system; a sensing module configured to detect electrical characteristics of the trailer lighting circuit; and a processing module configured to determine an operational status of the trailer lighting circuit based on the detected electrical characteristics.

15. A method of monitoring trailer lighting comprising: detecting electrical characteristics of one or more trailer lighting circuits; determining an operational status of the one or more trailer lighting circuits; and generating an alert indicative of a malfunction condition based on the determined operational status, wherein the detecting and determining are performed continuously during operation of a vehicle.
